(19) United States
(12) Patent Application Publication
(10) Pub. No.: US 2025/0273384 A1
(43) Pub. Date: Aug. 28, 2025

(54) PLANAR TRANSFORMER ASSEMBLY AND POWER ADAPTER

(71) Applicant: LITE-ON TECHNOLOGY CORPORATION, TAIPEI CITY (TW)

(72) Inventors: Chen CHEN, TAIPEI CITY (TW); De-Jia LU, TAIPEI CITY (TW); Yi-Wen CHENG, TAIPEI CITY (TW); Yong-Long SYU, TAIPEI CITY (TW); Kai-De CHEN, TAIPEI CITY (TW)

(21) Appl. No.: 18/830,653

(22) Filed: Sep. 11, 2024

Related U.S. Application Data
(60) Provisional application No. 63/557,626, filed on Feb. 26, 2024.

(51) Int. Cl. H01F 27/28; H01F 27/24; H01F 27/29; H05K 1/14; H05K 1/16; H05K 1/18

(52) U.S. Cl. CPC H01F 27/2804; H01F 27/24; H01F 27/29; H05K 1/144; H05K 1/165; H05K 1/181; H01F 2027/2809

(57) ABSTRACT

A planar transformer assembly and a power adapter are provided. The planar transformer assembly includes a first printed circuit board (PCB). The first PCB includes a magnetic core, a first primary PCB winding, a first secondary PCB winding and a second secondary PCB winding. The magnetic core passing through the first PCB includes a first cover plate, a second cover plate, and a first magnetic pillar. The first magnetic pillar is connected to the first cover plate. The first magnetic pillar is separated from the second cover plate by a first air gap. The first primary PCB winding is wrapped around a first portion of the first magnetic pillar. The first secondary PCB winding and the second secondary PCB winding are wrapped around a second portion of the first magnetic pillar below the first portion. The second portion is a single portion of the first magnetic pillar.

### CROSS REFERENCE TO RELATED APPLICATIONS

This application claims the benefit of U.S. Provisional Application No. 63/557,626, filed Feb. 26, 2024, the entirety of which is incorporated by reference herein.

### BACKGROUND OF THE INVENTION

### Field of the Invention

The present invention relates to a planar transformer assembly and a power adapter, and, in particular, it relates to the planar transformer of a planar transformer assembly and a power adapter.

### Description of the Related Art

With the advancement of technology and the rapid development of portable electronic products, more and more attention has been paid to the performance of switching converters in each of their applications. In recent years, due to major advances in power-electronics technology and the development of nanotechnology, a growing tendency in electronic devices has been towards designs that are slim and light, energy saving, and cost-effective. As a result of this, the design of its internal power converter also needs to trend towards designs that are slim and light, low energy consumption, high energy efficiency, and low fabrication cost. A power supply is generally required for most electrical appliances, to convert an input power from a power source (batteries or an AC power grid) into an output power with a specific rating. As technology advances, it has become routine for power supplies to operate more efficiently and to have a higher conversion efficiency.

### BRIEF SUMMARY OF THE INVENTION

An embodiment of the present invention provides a planar transformer assembly. The planar transformer assembly includes a first printed circuit board (PCB). The first printed circuit board includes a magnetic core, a first primary PCB winding, a first secondary PCB winding and a second secondary PCB winding. The magnetic core passes through the first PCB. The magnetic core includes a first cover plate, a second cover plate, and a first magnetic pillar. The second cover plate is located opposite the first cover plate. The first magnetic pillar is connected to the first cover plate and extends from the first cover plate to the second cover plate. The first magnetic pillar is separated from the second cover plate by a first air gap. The first primary PCB winding is wrapped around a first portion of the first magnetic pillar. The first secondary PCB winding and the second secondary PCB winding are wrapped around a second portion of the first magnetic pillar below the first portion of the first magnetic pillar. The second portion is a single portion of the first magnetic pillar.

An embodiment of the present invention provides a power adapter. The power adapter includes a main printed circuit board (PCB) and an affiliated printed circuit board (PCB). The main printed circuit board (PCB) has a pair of primary MOSFET switches and a high potential input port for conducting a modulated high potential current. The affiliated printed circuit board (PCB) is mounted on the main PCB. The affiliated PCB includes a primary side circuit and a center-tapped secondary side circuit. The primary side circuit includes primary PCB windings connected in series. The primary side circuit is configured to conduct the modulated high potential current. The center-tapped secondary side circuit includes a top secondary PCB winding circuit and a bottom secondary PCB winding circuit. Both the top secondary PCB winding circuit and the bottom secondary PCB winding circuit are stacked beneath the primary PCB winding circuit.

### BRIEF DESCRIPTION OF THE DRAWINGS

The present invention can be more fully understood by reading the subsequent detailed description and examples with references made to the accompanying drawings, wherein:

FIG. 1 is a schematic top view of a planar transformer assembly in accordance with some embodiments of the disclosure;

FIG. 2 is a block diagram of the planar transformer assembly of FIG. 1 in accordance with some embodiments of the disclosure;

FIG. 3 is an equivalent circuit diagram of a power adapter of the planar transformer assembly of FIG. 2 in accordance with some embodiments of the disclosure;

FIG. 4A is a schematic side view of a planar transformer formed in a printed circuit board of the planar transformer assembly of FIGS. 1-3 in accordance with some embodiments of the disclosure;

FIG. 4B is a schematic top view of various PCB layers of the planar transformer of FIG. 4A;

FIG. 5A is a schematic side view of a planar transformer formed in a printed circuit board of the planar transformer assembly of FIGS. 1-3 in accordance with some embodiments of the disclosure;

FIG. 5B is a schematic top view of various PCB layers of the planar transformer of FIG. 5A;

FIG. 6 is a partial schematic bottom view of a planar transformer assembly in accordance with some embodiments of the disclosure, showing secondary MOSFET switches of the planar transformer assembly of FIG. 1 in accordance with some embodiments of the disclosure; and

FIG. 7 is a partial cross-sectional view of FIG. 5A, showing the electrical connections between the secondary MOSFET switches and secondary PCB winding circuits of the planar transformer in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

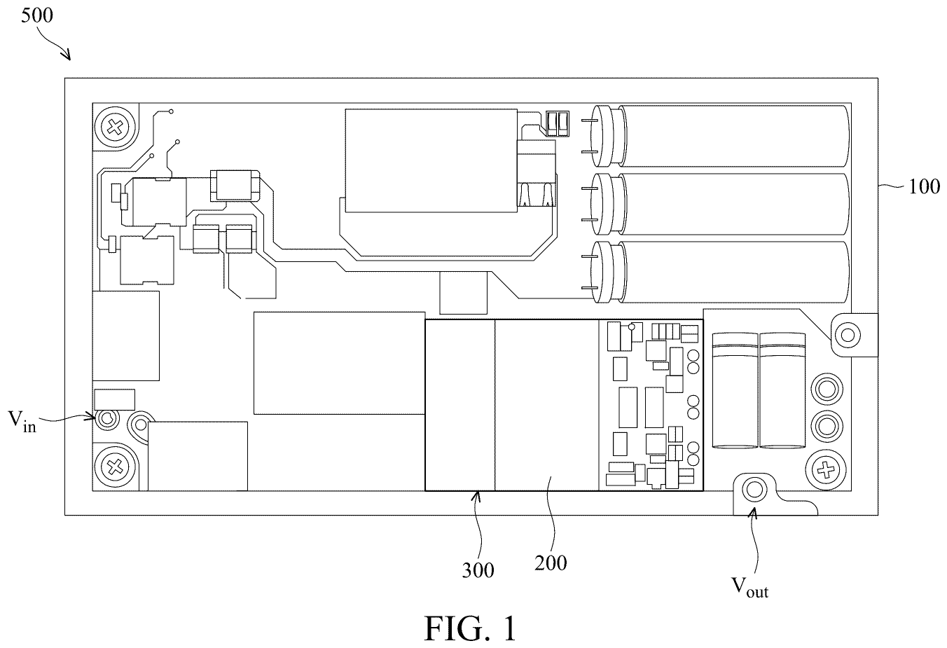

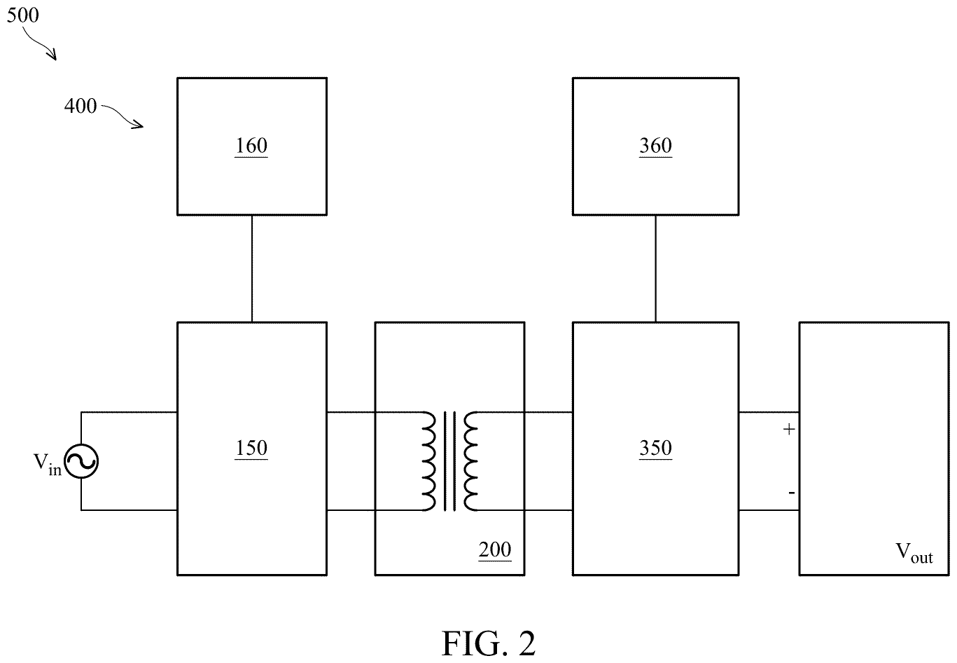

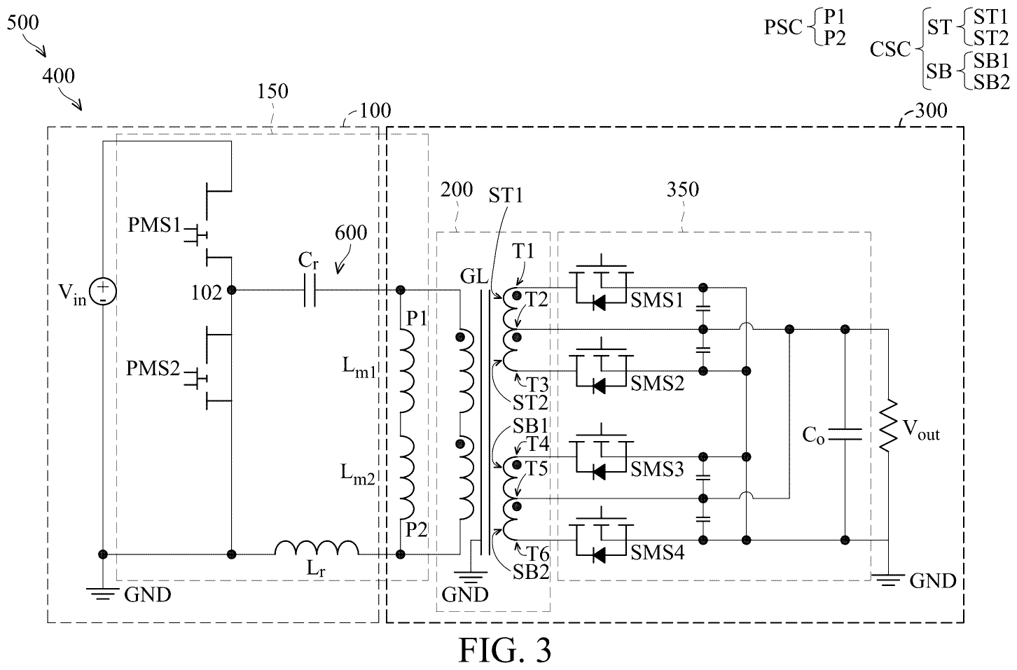

FIG. 1 is a schematic top view of a planar transformer assembly 500 in accordance with some embodiments of the disclosure. FIG. 2 is a block diagram of the planar transformer assembly 500 of FIG. 1 in accordance with some embodiments of the disclosure. FIG. 3 is an equivalent circuit diagram of a power adapter 400 (e.g., an LLC resonant converter) of the planar transformer assembly 500 of FIGS. 1 and 2 in accordance with some embodiments of the disclosure. In some embodiments, the planar transformer assembly 500 includes the power adapter (e.g., an AC-to-DC power adapter) 400 using a planar transformer 200 and fabricated using a multi-layer printed circuit board (PCB). For example, primary and secondary PCB windings of the planar transformer 200 of the planar transformer assembly 500 are formed by various conductive layers and vias in the PCB. In addition, the primary PCB windings and the secondary PCB windings of the planar transformer 200 are separated from each other by a core substrate or by dielectric layers (formed of polypropylene (PP) or pre-preg) of a build-up layer structure of the PCB.

As shown in FIG. 1, the planar transformer assembly 500 includes a main printed circuit board (PCB) 100 and an affiliated printed circuit board (PCB) 300 mounted on the main PCB 100.

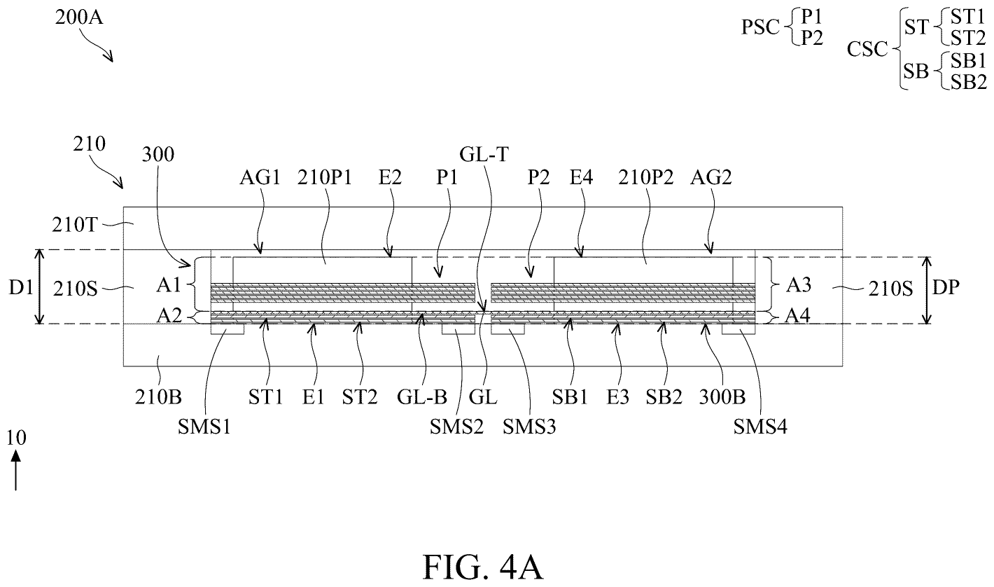

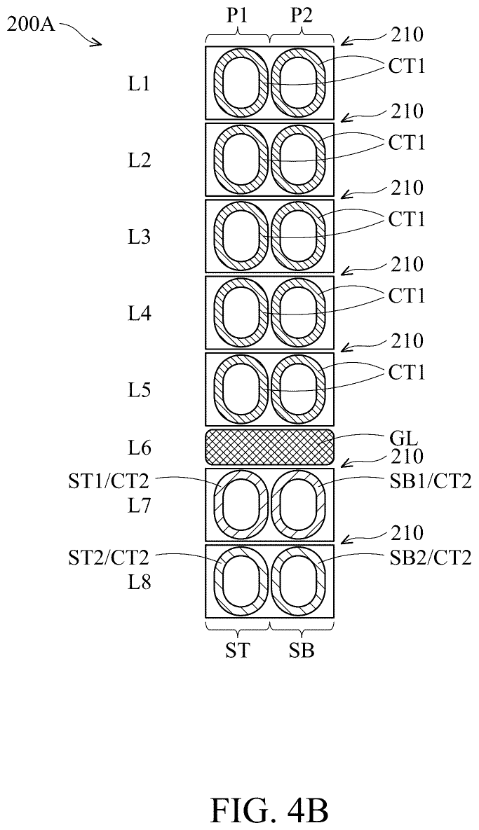

As shown in FIGS. 2 and 3, the power adapter 400 of the planar transformer assembly 500 includes a primary-side signal generating circuit 150, the planar transformer 200 (including planar transformers 200A and 200B shown in FIGS. 4A and 4B), and a secondary-side rectifying circuit 350. The power adapter 400 may receive AC power from a high potential (high voltage) input port Vᵢₙ. The high potential input port Vᵢₙ is configured to conduct a modulated high potential current. In addition, the power adapter 400 may configured to provide a converted DC voltage to an output port Vₒᵤₜ.

As shown in FIGS. 1-3, the main printed circuit board (PCB) 100 may include the high potential input port Vᵢₙ and the primary-side signal generating circuit 150. The primary-side signal generating circuit 150 arranged on the main printed circuit board (PCB) 100 includes a pair of primary MOSFET switches PMS1, PMS2, an inductor Lᵣ (also called a resonant inductor Lᵣ), a capacitor Cᵣ (also called a resonant capacitor Cᵣ), and the high potential input port Vᵢₙ.

In some embodiments, the pair of primary MOSFET switches PMS1, PMS2 is implemented in half-bridge topologies. In addition, the MOSFET switches PMS1 and PMS2 connected in series are configured to generate a switched signal from the high potential input port Vᵢₙ.

As shown in FIGS. 1-3, the affiliated printed circuit board (PCB) 300 includes a pair of inductors Lₘ₁, Lₘ₂ (also called magnetizing inductors Lₘ₁, Lₘ₂), the planar transformer 200, the secondary-side rectifying circuit 350 and the output Vₒᵤₜ.

The capacitor Cᵣ and the inductor Lᵣ on the main printed circuit board (PCB) 100, and the pair of inductors Lₘ₁, Lₘ₂ on the affiliated printed circuit board (PCB) 300 are connected in series. The pair of inductors Lₘ₁, Lₘ₂ and the capacitor Cᵣ are connected to (coupled to) a connection point 102 and a ground terminal GND of the pair of primary MOSFET switches PMS1, PMS2 to form an LLC structure 600 (e.g., an LLC resonant tank). The LLC structure 600 is configured to provide the high potential input port Vᵢₙ with the modulated high potential current (The LLC structure 600 is configured to output a resonant sinusoidal current that gets scaled and rectified by the planar transformer 200 and the secondary-side rectifying circuit 350).

The planar transformer 200 arranged on the affiliated PCB 300 includes a primary side circuit PSC and a center-tapped secondary side circuit CSC isolated from each other. The planar transformer 200 is configured to step down the voltage from the primary side circuit PSC to the center-tapped secondary side circuit CSC. The primary side circuit PSC includes primary PCB windings P1, P2 connected in series. The pair of inductors Lₘ₁, Lₘ₂ and first and second ends of the primary side circuit PSC of the planar transformer 200 are connected in parallel. The inductor Lᵣ, the second end of the primary side circuit PSC and the capacitor Cᵣ are connected in series. The first end of the primary side circuit PSC is connected to the connection point 102 of the pair of primary MOSFET switches PMS1, PMS2, by the inductor capacitor Cᵣ. In addition, the second end of the primary side circuit PSC is connected to the GND of the pair of primary MOSFET switches PMS1, PMS2, by the inductor Lᵣ. The primary side circuit PSC is configured to conduct the modulated high potential current from the primary-side signal generating circuit 150.

The center-tapped secondary side circuit CSC includes a top secondary PCB winding circuit ST and a bottom secondary PCB winding circuit SB. The top secondary PCB winding circuit ST and the bottom secondary PCB winding circuit SB are connected in parallel.

The top secondary PCB winding circuit ST includes a secondary PCB winding ST1 and a secondary PCB winding ST2 connected in series. In addition, the secondary PCB winding ST1 and the secondary PCB winding ST2 are wound in opposite directions in order to have opposite voltage potential directions. For example, one of the secondary PCB windings ST1, ST2 is wound clockwise and the other the secondary PCB windings ST1, ST2 is wound anti-clockwise. As shown in FIG. 3, the secondary PCB winding ST1 has opposite terminals T1 and T2. The secondary PCB winding ST2 has opposite terminals T2 and T3. In some embodiments, the secondary PCB winding ST1 and the secondary PCB winding ST2 have the common terminal T2 which is provided as the output to the output Vₒᵤₜ. That is to say, the terminal T2 of the secondary PCB winding ST1 is connected to the terminal T2 of the secondary PCB winding ST2. Therefore, the top secondary PCB winding circuit ST formed by the secondary PCB windings ST1 and ST2 is also called a center-tapped secondary circuit ST.

Similarly, the bottom secondary PCB winding circuit SB includes a secondary PCB winding SB1 and a secondary PCB winding SB2 connected in series. In addition, the secondary PCB winding SB1 and the secondary PCB winding SB2 are wound in opposite directions in order to have opposite voltage potential directions. For example, one of the secondary PCB windings SB1, SB2 is wound clockwise and the other the secondary PCB windings SB1, SB2 is wound anti-clockwise. As shown in FIG. 3, the secondary PCB winding SB1 has opposite terminals T4 and a T5. The secondary PCB winding SB2 has opposite terminals T5 and T6. In some embodiments, the secondary PCB winding SB1 and the secondary PCB winding SB2 have the common terminal T5 which is provided as the output to the output Vₒᵤₜ. That is to say, the terminal T5 of the secondary PCB winding SB1 is connected to the terminal T5 of the fourth secondary PCB winding SB2. Therefore, the bottom secondary PCB winding circuit SB formed by the secondary PCB windings SB1 and SB2 is also called a center-tapped secondary circuit SB.

The planar transformer 200 arranged on the affiliated PCB 300 further includes a shielding layer GL sandwiched between the center-tapped secondary side circuit CSC (including the top secondary PCB winding circuit ST and the bottom secondary PCB winding circuit SB) and the primary side circuit PSC (including the primary PCB windings P1, P2). In some embodiments, the shielding layer GL is connected to a ground terminal GND for suppressing common mode noise induced on the center-tapped secondary side circuit CSC.

The secondary-side rectifying circuit 350 arranged on the affiliated PCB 300 includes at least two pairs of secondary MOSFET switches SMS1, SMS2, SMS3, SMS4 and a capacitor Cₒ (also called an output capacitor Cₒ). The two pairs of secondary MOSFET switches SMS1, SMS2, SMS3, SMS4 are electrically connected to the top secondary PCB winding circuit ST and the bottom secondary PCB winding circuit SB. More specifically, the pair of secondary MOSFET switches SMS1, SMS2 is electrically connected to the secondary PCB windings ST1, ST2 of the top secondary PCB winding circuit ST. The pair of secondary MOSFET switches SMS3, SMS4 is electrically connected to the secondary PCB windings SB1, SB2 of the bottom secondary PCB winding circuit SB. The output of the center-tapped secondary side circuit CSC is rectified by the two pairs of secondary MOSFET switches SMS1, SMS2, SMS3, SMS4 and filtered by the capacitor Co to generate a DC voltage to an output port Vₒᵤₜ.

In some embodiments, the power adapter 400 of the planar transformer assembly 500 further includes analog integrated circuits (ICs) 160 and 360. The analog integrated circuit 160 is connected to (coupled to) the primary-side signal generating circuit 150. In addition, the analog integrated circuit 360 is connected to (coupled to) the secondary-side rectifying circuit 350. The analog integrated circuits (ICs) 160 and 360 are configured to control the LLC structure 600 of the primary-side signal generating circuit 150 and the secondary-side rectifying circuit 350.

FIG. 4A is a schematic side view of the planar transformer 200A formed in the affiliated PCB 300 of the planar transformer assembly 500 of FIGS. 1-3 in accordance with some embodiments of the disclosure. FIG. 4B is a schematic top view of various PCB layers of the planar transformer 200A of FIG. 4A. For illustration of the arrangements of the primary and secondary windings and the shielding layer of the planar transformer 200A, the core substrate or the dielectric layers of the affiliated PCB 300 are not shown in FIGS. 4A and 4B, and a magnetic core 210 of the planar transformer 200A is shown in FIG. 4B.

As shown in FIG. 4A, the planar transformer 200A of the planar transformer assembly 500 includes the magnetic core 210, the primary PCB windings P1, P2, the secondary PCB windings ST1, ST2, SB1, SB2, and the shielding layer GL.

The magnetic core 210 may be formed passing through the opening (not shown) formed through the affiliated PCB 300. In addition, the magnetic core 210 may be disposed around the primary side circuit PSC (including the primary PCB windings P1, P2) and the center-tapped secondary side circuit CSC (including the secondary PCB windings ST1, ST2, SB1, SB2) formed on the affiliated PCB 300. In some embodiments, the magnetic core 210 includes cover plates 210B and 210T, a side core 210S, and magnetic pillars 210P1 and 201P2. The cover plate 210T is located opposite the cover plate 210B. The side core 210S is disposed between to affix the cover plates 210B and 210T. The magnetic pillar 210P1 is disposed on the cover plate 210B. In addition, the magnetic pillar 201P1 extends from the first cover plate 210B to the second cover plate 210T in a direction 10 (i.e., the extension direction 10 of the magnetic pillar 201P1). The magnetic pillar 201P2 is disposed on the cover plate 210B and beside the magnetic pillar 210P1. In addition, the magnetic pillar 201P2 extends from the first cover plate 210B to the second cover plate 210T in the extension direction 10.

As shown in FIG. 4A, the magnetic pillar 210P1 has opposite ends E1 and E2. The magnetic pillar 201P2 has opposite ends E3 and E4. The end E1 of the magnetic pillar 210P1 and the end E3 of the magnetic pillar 210P2 are connected to the cover plate 210B. In some embodiments, the first magnetic pillar 210P1 and the second magnetic pillar 201P2 have a height DP (i.e., the distance between the opposite ends E1 and E2 of the magnetic pillar 210P1 or between the opposite ends E3 and E4 of the magnetic pillar 210P2) that is shorter than a first distance D1 between the first cover plate 210B and the second cover plate 210T in the direction 10. Therefore, the end E2 of the magnetic pillar 210P1 is close to and separated from the cover plate 210T by an air gap AG1. The end E4 of the magnetic pillar 210P1 is close to the cover plate 210T but separated from it by an air gap AG2.

The magnetic pillar 210P1 has a portion A1 and a portion A2 beside the portion A1 in the direction 10. The portion A1 is located closer to the end E2 and the air gap AG1 than the portion A2. In addition, the portion A2 is located closer to the end E1 than the portion A1. In addition, the magnetic pillar 210P2 has a portion A3 and a portion A4 beside the portion A3 in the direction 10. The portion A3 is located closer to the end E4 and the air gap AG2 than the portion A4. In addition, the portion A4 is located closer to the end E3 than the portion A3.

In some embodiments, the affiliated PCB 300 including the primary and secondary windings is located close to the first cover plate 210B and away from the air gaps AG1, AG2. As shown in FIGS. 3 and 4A, the primary PCB winding P1 of the primary side circuit PSC and the secondary PCB windings ST1 and ST2 of the top secondary PCB winding circuit ST of the center-tapped secondary side circuit CSC are around the magnetic pillar 210P1. More specifically, the primary PCB winding P1 is wrapped around the portion A1 of the magnetic pillar 210P1. The secondary PCB windings ST1 and ST2 are wrapped around the portion A2 below the portion A1. In some embodiments, the secondary PCB windings ST1 and ST2 are wound around the portion A2 of the magnetic pillar 210P1 in opposite directions. For example, one of the secondary PCB windings ST1, ST2 is wound clockwise and the other the secondary PCB windings ST1, ST2 is wound anti-clockwise. In addition, the secondary PCB windings ST1 and ST2 are located away from the air gap AG1. In other words, the primary PCB winding P1 of the primary side circuit PSC is closer to the air gap AG1 than the secondary PCB windings ST1 and ST2 of the top secondary PCB winding circuit ST of the center-tapped secondary side circuit CSC. In some embodiments, the portion A2 is a single portion of the magnetic pillar 210P1.

Similarly, as shown in FIGS. 3 and 4A, the primary PCB winding P2 of the primary side circuit PSC and the secondary PCB windings SB1 and SB2 of the bottom secondary PCB winding circuit SB of the center-tapped secondary side circuit CSC are around the magnetic pillar 210P2. More specifically, the first primary PCB winding P2 is wrapped around the portion A3 of the magnetic pillar 210P2. The secondary PCB windings SB 1 and SB2 are wrapped around the portion A4 below the portion A3. In some embodiments, the secondary PCB windings SB1 and SB2 are wound around the portion A4 of the magnetic pillar 210P2 in opposite directions. For example, one of the secondary PCB windings SB1, SB2 is wound clockwise and the other the secondary PCB windings SB1, SB2 is wound anti-clockwise.In addition, the secondary PCB windings SB1 and SB2 are located away from the air gap AG2. In other words, the primary PCB winding P2 of the primary side circuit PSC is closer to the air gap AG2 than the secondary PCB windings SB1 and SB2 of the bottom secondary PCB winding circuit SB of the center-tapped secondary side circuit CSC. In some embodiments, the portion A4 is a single portion of the magnetic pillar 210P2.

As shown in FIG. 4A, both the top secondary PCB winding circuit ST and the bottom secondary PCB winding circuit SB are stacked beneath the primary PCB windings P1, P2 in the direction 10. In other words, the primary PCB winding P1 of the primary side circuit PSC is stacked on the secondary PCB windings ST1 and ST2 of the top secondary PCB winding circuit ST of the center-tapped secondary side circuit CSC in the extension direction 10 of the magnetic pillar 210P1. Therefore, the primary PCB winding PI may generate excitation current flowing through the secondary PCB windings ST1 and ST2.

Similarly, the primary PCB winding P2 of the primary side circuit PSC is stacked on the secondary PCB windings SB1 and SB2 of the bottom secondary PCB winding circuit SB of the center-tapped secondary side circuit CSC in the extension direction 10 of the magnetic pillar 210P2. Therefore, the primary PCB winding P2 may generate excitation current flowing through the secondary PCB windings SB1 and SB2.

As shown in FIGS. 3 and 4A, the shielding layer GL of the planar transformer 200A is a single shielding layer located below the primary PCB windings P1, P2 and above the secondary PCB windings ST1, ST2, SB1, SB2. In other words, the shielding layer GL is arranged at single side of each of the primary PCB windings P1, P2 away from the air gaps AG1 and AG2. It is noted that there is no shielding layer GL disposed between the air gap AG1 and the primary PCB winding P1, or between the air gap AG2 and the primary PCB winding P2. In addition, the single shielding layer GL has a top surface GL-T and a bottom surface GL-B. The top surface GL-T is located close to the air gaps AGI and AG2. The bottom surface GL-B is located away from the air gaps AG1 and AG2. The primary PCB windings P1, P2 are disposed above the top surface GL-T of the single shielding layer GL. The secondary PCB windings ST1, ST2, SB1, SB2 are disposed below the bottom surface GL-B of the single shielding layer GL.

As shown in FIG. 4B, the affiliated PCB 300 including the planar transformer 200A is an 8-layer PCB. The 8-layer affiliated PCB 300 includes a first conductive layer L1, a second conductive layer L2, a third conductive layer L3, a fourth conductive layer L4, a fifth conductive layer L5, a sixth conductive layer L6, a seventh conductive layer L7, and an eighth conductive layer L8 arranged in sequence. In addition, the first conductive layer L1 is located close to the air gaps AG1 and AG2 than the second conductive layer L2 to the eighth conductive layer L8.

In the planar transformer 200A, the primary PCB windings P1, P2 are formed by the first conductive layer L1, the second conductive layer L2, the third conductive layer L3, the fourth conductive layer L4 and the fifth conductive layer L5 of the 8-layer affiliated PCB 300. In some embodiments, each of the primary PCB windings P1, P2 has 1-turn conductive trace CT1 in each of the first conductive layer L1 to the fifth conductive layer L5. In other words, each of the first conductive layer L1 to the fifth conductive layer L5 includes two 1-turn conductive traces CT1 arranged side by side. One is for the primary PCB winding P1, and another is for the primary PCB winding P2. In each of the primary PCB windings P1, P2, the 1-turn conductive traces CT1 in the first conductive layer L1 to the fifth conductive layer L5 are connected in series by vias (not shown). In addition, the primary PCB windings P1, P2 are connected in series by vias (not shown) to form a 10-turn primary PCB winding. In other words, the first and second primary PCB windings have 10 turns in total.

In some embodiments, the single shielding layer GL is formed by the sixth conductive layer L6 of the 8-layer affiliated PCB 300.

The secondary PCB windings ST1, SB1 are formed by the seventh conductive layer L7 of the 8-layer affiliated PCB 300. In addition, the secondary PCB windings ST2, SB2 are formed by the eighth conductive layer L8 of the affiliated PCB 300. In some embodiments, each of the secondary PCB windings ST1, SB1 has 1-turn conductive trace CT2 in the seventh conductive layer L7. Each of the secondary PCB windings ST2, SB2 has 1-turn conductive trace CT2 in each of the eighth conductive layer L8. In other words, each of the seventh and eighth conductive layers L7, L8 includes two 1-turn conductive traces CT2 arranged side by side. One is for the secondary PCB winding ST1 (or the secondary PCB winding ST2), and another is for the secondary PCB winding SB1 (or the secondary PCB winding SB2). Each of the secondary PCB windings ST1, SB1, ST2, SB2 forms a 1-turn secondary PCB winding. In other words, each of the secondary PCB windings ST1, SB1, ST2, SB2 has 1 turn.

In the planar transformer 200A, the turns ratio of the primary PCB windings P1 and P2 to any of the secondary PCB windings ST1, SB1, ST2, SB2 in each of the top secondary PCB winding circuit ST and the bottom secondary PCB winding circuit SB is 10:1. In other words, the turns ratio of the primary PCB windings P1 and P2 to the secondary PCB windings ST1, SB1, ST2, SB2 wound clockwise or anti-clockwise in each of the top secondary PCB winding circuit ST and the bottom secondary PCB winding circuit SB of the planar transformer 200A is 10:1.

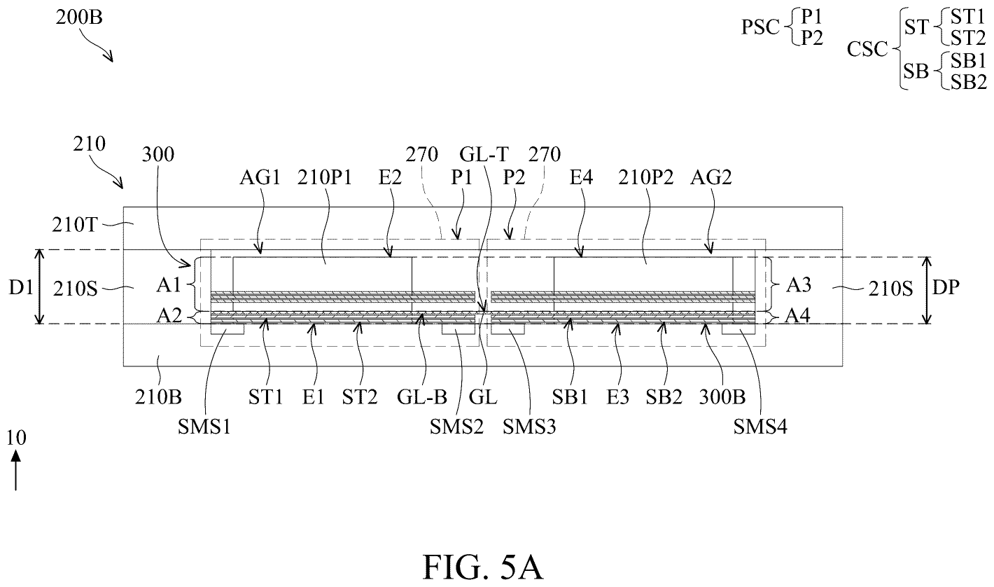

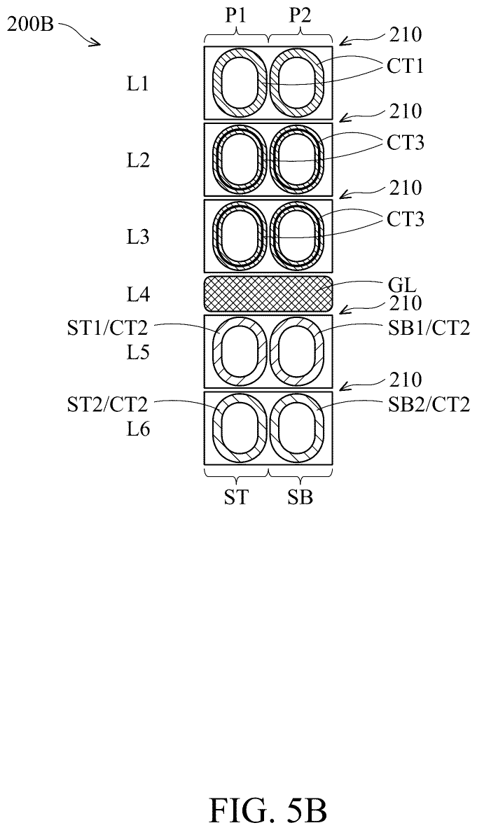

FIG. 5A is a schematic side view of the planar transformer 200B formed in the affiliated PCB 300 of the planar transformer assembly 500 of FIGS. 1-3 in accordance with some embodiments of the disclosure. FIG. 5B is a schematic top view of various PCB layers of the planar transformer 200A of FIG. 5A. Elements of the embodiments hereinafter, that are the same or similar as those previously described with reference to FIGS. 4A and 4B, are not repeated for brevity. For illustration of the arrangements of the primary and secondary windings and the shielding layer of the planar transformer 200B, the core substrate or the dielectric layers of the affiliated PCB 300 are not shown in FIGS. 5A and 5B, and the magnetic core 210 of the planar transformer 200B is shown in FIG. 5B.

One of the differences between the planar transformer 200A shown in FIGS. 4A and 4B and the planar transformer 200B shown in FIGS. 5A and 5B is that the affiliated PCB 300 including the planar transformer 200B is a 6-layer PCB. The 6-layer affiliated PCB 300 includes a first conductive layer L1, a second conductive layer L2, a third conductive layer L3, a fourth conductive layer L4, a fifth conductive layer L5, and a sixth conductive layer L6 arranged in sequence. In addition, the first conductive layer L1 is located close to the air gaps AG1 and AG2 than the second conductive layer L2 to the sixth conductive layer L6.

In the planar transformer 200B, the primary PCB windings P1, P2 are formed by the first conductive layer L1, the second conductive layer L2 and the third conductive layer L3 of the 6-layer affiliated PCB 300. In some embodiments, each of the primary PCB windings P1, P2 has 1-turn conductive trace CT1 in one of the first conductive layer L1 to the third conductive layer L3. In addition, each of the primary PCB windings P1, P2 has two 2-turn conductive trace CT3 in other two of the first conductive layer L1 to the third conductive layer L3. For example, each of the primary PCB windings P1, P2 has 1-turn conductive trace CT1 in the first conductive layer L1 and two 2-turn conductive traces CT2 in the second conductive layer L2 and the third conductive layer L3. In other words, the first conductive layer L1 includes two 1-turn conductive traces CT1 arranged side by side. One is for the primary PCB winding P1, and another is for the primary PCB winding P2. Each of the second conductive layer L2 and the third conductive layer L3 includes two 2-turn conductive traces CT3 arranged side by side. One is for the primary PCB winding P1, and another is for the primary PCB winding P2.

In each of the primary PCB windings P1, P2, the 1-turn conductive trace CT1 in the first conductive layer L1 and the two 2-turn conductive traces CT3 in the second conductive layer L2 and the third conductive layer L3 are connected in series by vias (not shown). In addition, the primary PCB windings P1, P2 are connected in series by vias (not shown) to form a 10-turn primary PCB winding. In other words, the first and second primary PCB windings have 10 turns in total.

In some embodiments, the single shielding layer GL is formed by the fourth conductive layer L4 of the 6-layer affiliated PCB 300.

The secondary PCB windings ST1, SB1 are formed by the fifth conductive layer L5 of the 6-layer affiliated PCB 300. In addition, the secondary PCB windings ST2, SB2 are formed by the sixth conductive layer L6 of the 6-layer affiliated PCB 300. In some embodiments, each of the secondary PCB windings ST1, SB1 has 1-turn conductive trace CT2 in the fifth conductive layer L5. Each of the secondary PCB windings ST2, SB2 has 1-turn conductive trace CT2 in the sixth conductive layer L6. In other words, each of the fifth conductive layer L5 and sixth conductive layer L6 includes two 1-turn conductive traces CT2 arranged side by side. One is for the secondary PCB winding ST1 (or the secondary PCB winding ST2), and another is for the secondary PCB winding SB1 (or the secondary PCB winding SB2). Each of the secondary PCB windings ST1, SB1, ST2, SB2 forms a 1-turn secondary PCB winding. In other words, each of the secondary PCB windings ST1, SB1, ST2, SB2 has 1 turn.

In the planar transformer 200B, the turns ratio of the primary PCB windings P1 and P2 to any of the secondary PCB windings ST1, SB1, ST2, SB2 in each of the top secondary PCB winding circuit ST and the bottom secondary PCB winding circuit SB is 10:1. In other words, the turns ratio of the primary PCB windings P1 and P2 to the secondary PCB windings ST1, SB1, ST2, SB2 wound clockwise or anti-clockwise in each of the top secondary PCB winding circuit ST and the bottom secondary PCB winding circuit SB of the planar transformer 200B is 10:1.

The planar transformer 200 has the following advantages. In some embodiments, the planar transformer 200 uses a single shielding layer GL arranged at single side of the primary side circuit PSC2 away from the air gaps AG1 and AG2. Therefore, the primary side circuit PSC (including the primary PCB windings P1, P2) and the whole center-tapped secondary side circuit CSC (including the secondary PCB windings ST1, ST2, SB1, SB2) are disposed close to opposite surfaces (the top surface GL-T and the bottom surface GL-B) of the same shielding layer GL. The sequence of the arrangement of the primary PCB windings P1, P2, the single shielding layer GL and the secondary PCB windings ST1, ST2, SB1, SB2 of the planar transformer 200 may be called a PSS (primary winding-secondary winding-secondary winding) structure, where S is the secondary side winding, and P is the primary side winding. Compared with the conventional planar transformer which uses two shielding layers to isolate the primary and secondary windings (having a SPS (secondary winding-primary winding-secondary winding) structure), the planar transformer 200 of the planar transformer assembly 500 may release at least one PCB conductive layer. The released PCB conductive layer may be used for the primary PCB windings. Therefore, the resistance (e.g., DC resistance, R_{dc}) of the primary windings can be reduced.

In some embodiments, the magnetic core 210 of the planar transformer 200 may include the air gaps AG1 and AG2 to provide the desired inductance for energy storage in the planar transformer 200. In addition, the secondary PCB windings ST1, ST2, SB1, SB2 are arranged away from the air gaps AG1 and AG2. Compared with the conventional planar transformer having the SPS structure, the current flow induced in the secondary PCB windings ST1, ST2, SB1, SB2 of the planar transformer 200 of the planar transformer assembly 500 is more uniform.

In some embodiments, the primary and secondary PCB windings of the planar transformer 200 are formed in the double-sided PCB. Considering the tradeoff between the impedance, leakage inductance, power loss (e.g., the DC resistance loss in the primary and secondary windings, and eddy-current loss and hysteresis loss in the magnetic core), and the fabrication cost, the planar transformer assembly 500 may use a 6-layer PCB or an 8-layer PCB to form the primary and secondary PCB windings of the planar transformer 200. For example, the primary PCB windings P1, P2 and the secondary PCB windings ST1, ST2, SB1, SB2 of the planar transformer 200A are formed in the 8-layer affiliated PCB 300. The primary PCB windings P1, P2 and the secondary PCB windings ST1, ST2, SB1, SB2 of the planar transformer 200B are formed in the 6-layer affiliated PCB 300. However, the planar transformer 200 may also be applied to other printed circuit boards with different numbers of conductive layers.

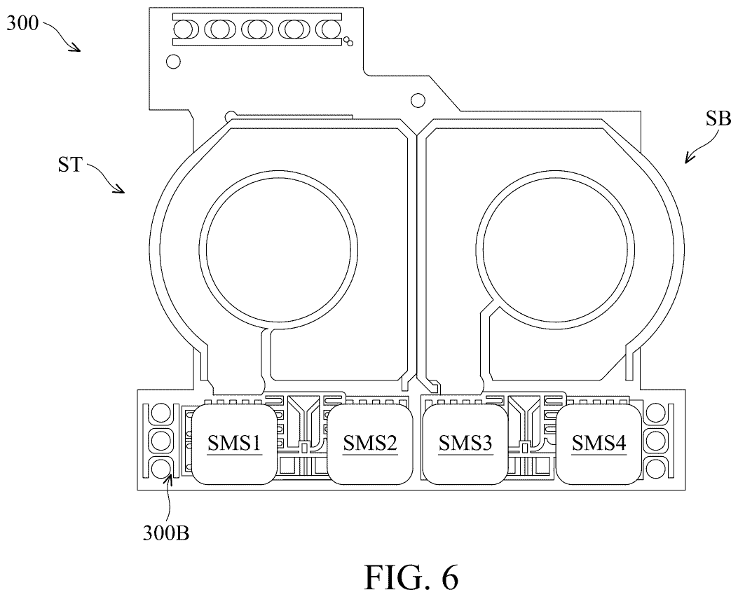

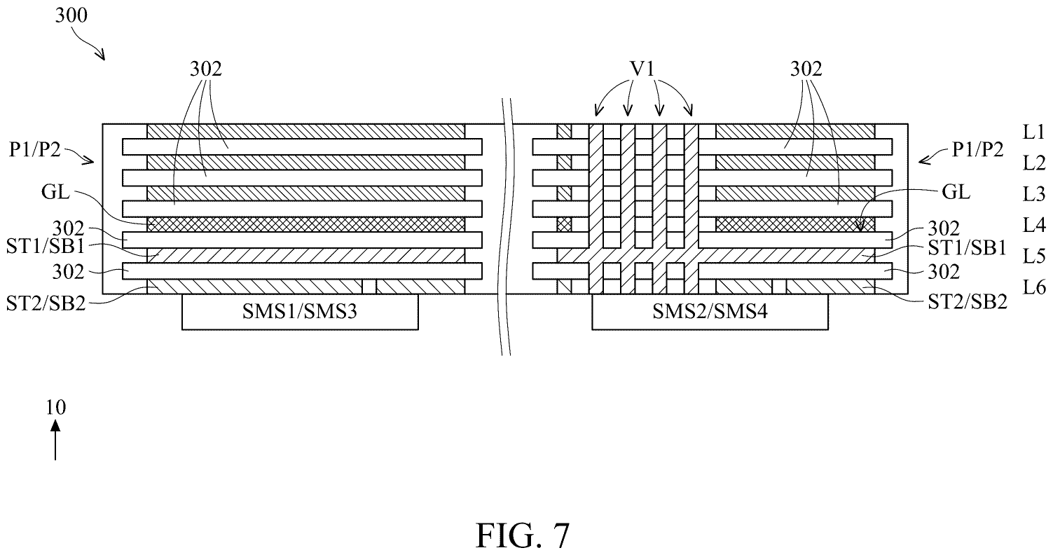

FIG. 6 is a partial schematic bottom view of a portion of the affiliated PCB 300 of the planar transformer assembly 500 in accordance with some embodiments of the disclosure, showing the secondary MOSFET switches SMS1, SMS2, SMS3, SMS4 of the planar transformer assembly 500 of FIG. 1 in accordance with some embodiments of the disclosure. FIG. 7 is a cross-sectional view of portions 270 of FIG. 5A, showing the electrical connections between the secondary MOSFET switches SMS1, SMS2, SMS3, SMS4 and the top secondary PCB winding circuit ST and the bottom secondary PCB winding circuit SB of the planar transformer 500 in accordance with some embodiments of the disclosure.

As shown in FIGS. 5A and 6, the 6-layer affiliated PCB 300 further includes two pairs of secondary MOSFET switches SMS1, SMS2, SMS3, SMS4 mounted on a back side 300B of the affiliated PCB 300 and close to the planar transformer 200B with advantages of heat dissipation. In addition, the back side 300B of the affiliated PCB 300 is a planar surface to facilitate the pairs of secondary MOSFET switches SMS1, SMS2, SMS3, SMS4 mounted thereon. For example, the pair of secondary MOSFET switches SMS1, SMS2 are mounted on the back side 300B of the affiliated PCB 300 and close to the top secondary PCB winding circuit ST of the center-tapped secondary side circuit CSC. In addition, the pair of secondary MOSFET switches SMS3, SMS4 are mounted on the back side 300B of the affiliated PCB 300 and close to the bottom secondary PCB winding circuit SB of the center-tapped secondary side circuit CSC. Moreover, the two pairs of secondary MOSFET switches SMS1, SMS2, SMS3, SMS4 are located away from the primary PCB windings P1, P2 and the air gaps AG1 and AG2. In some embodiments, the two pairs of secondary MOSFET switches SMS1, SMS2, SMS3, SMS4 of the 8-layer affiliated PCB 300 have similar arrangements relative to the planar transformer 200A as shown in FIG. 4A. Compared with the conventional planar transformer (having the SPS structure) in which the secondary MOSFET switches mounted on opposite sides of the affiliated PCB, the locations of the two pairs of secondary MOSFET switches SMS1, SMS2, SMS3, SMS4 may have benefits of a low resistance loss.

As shown in FIG. 7, in the pair of secondary MOSFET switches SMS1, SMS2, one of the secondary MOSFET switches SMS1, SMS2 (e.g., the secondary MOSFET switch SMS2) is electrically connected to the secondary PCB winding ST1 of the top secondary PCB winding circuit ST, and without being connected to the bottom secondary PCB winding circuit SB, through one or more vias (output vias) V1. The one or more vias V1 may be conducted from a first protruding portion of the conducting trace of the fifth conductive layer L5, formed passing through the core substrate/dielectric layers 302 between the fifth conductive layer L5 and the sixth conductive layer L6 of the affiliated PCB 300 in the direction 10, and finally conducted to the input port of the MOSFET switch SMS2. In addition, another one of the secondary MOSFET switches SMS1, SMS2 (e.g., the secondary MOSFET switch SMS1) is electrically connected to the secondary PCB winding ST2 of the top secondary PCB winding circuit ST through a conducting port closed to the bottom face of the affiliated PCB 300. The conducting trace of the sixth conductive layer L6 has a second protruding portion beneath the first protruding portion of the conducting trace of the sixth conductive layer L5, and the first protruding portion is longer than the second protruding portion so as to allocate the one or more vias on the first protruding portion without conducting the one or more vias to the conducting trace of the sixth conductive layer L6.

Similarly, in the pair of secondary MOSFET switches SMS3, SMS4, one of the secondary MOSFET switches SMS3, SMS4 (e.g., the secondary MOSFET switch SMS4) is electrically connected to the secondary PCB winding SB1 of the bottom secondary PCB winding circuit SB, and without being connected to the top secondary PCB winding circuit ST, through the vias V1. In addition, another of the secondary MOSFET switches SMS3, SMS4 (e.g., the secondary MOSFET switch SMS4) may be electrically connected to the secondary PCB winding SB2 of the bottom secondary PCB winding circuit SB without the vias V1.

In the planar transformer assembly 500, a distance between the pair of primary MOSFET switches PMS1, PMS2 and the high potential input port Vᵢₙ is greater than a distance between the secondary MOSFET switches SMS1, SMS2, SMS3, SMS4 and the vias V1 according to the PCB clearance rules.

Embodiments provide a planar transformer assembly, such as a power adapter. The planar transformer assembly includes a first printed circuit board (PCB). The first PCB includes a magnetic core, a first primary PCB winding, a first secondary PCB winding and a second secondary PCB winding. The magnetic core passes through the first PCB and includes a first cover plate, a second cover plate and a first magnetic pillar. The first magnetic pillar is connected to the first cover plate and extends from the first cover plate to the second cover plate. The first magnetic pillar is separated from the second cover plate by a first air gap.

The planar transformer assembly further includes a planar transformer composed of the magnetic core, the first primary PCB winding, a first secondary PCB winding and the second secondary PCB winding and a single shielding layer. The first primary PCB winding is wrapped around a first portion of the first magnetic pillar. The first secondary PCB winding and a second secondary PCB winding are wrapped around a second portion of the first magnetic pillar below the first portion of the first magnetic pillar. The second portion is a single portion of the first magnetic pillar. The single shielding layer is located below the first primary PCB winding and above the first secondary PCB winding and the second secondary PCB winding. The shielding layer is connected to a ground terminal.

In some embodiments, the first portion of the first magnetic pillar is closer to the first air gap than the second portion of the first magnetic pillar. In some embodiments, each of the first secondary PCB winding and the second secondary PCB winding has a first terminal and a second terminal, and the second terminal of the first secondary PCB winding is connected to the first terminal of the second secondary PCB winding.

In some embodiments, the magnetic core further includes a second magnetic pillar beside the first magnetic pillar. The second magnetic pillar is connected to the first cover plate and extends from the first cover plate to the second cover plate. The second magnetic pillar is separated from the second cover plate by a second air gap. In some embodiments, the first PCB further includes a second primary PCB winding, a third secondary PCB winding and a fourth secondary PCB winding. The second primary PCB winding is wrapped around a third portion of the second magnetic pillar. The first primary PCB winding and the second primary PCB winding are connected in series. The third secondary PCB winding and the fourth secondary PCB winding are wrapped around a fourth portion of the second magnetic pillar below the third portion of the second magnetic pillar. The fourth portion is a single portion of the second magnetic pillar.

In some embodiments, the third portion of the second magnetic pillar is closer to the second air gap than the fourth portion of the second magnetic pillar. In some embodiments, each of the third secondary PCB winding and the fourth secondary PCB winding has a third terminal and a fourth terminal, and the fourth terminal of the third secondary PCB winding is connected to the third terminal of the fourth secondary PCB winding In some embodiments, the first secondary PCB winding and the second secondary PCB winding form a first center-tapped secondary circuit, the third secondary PCB winding and the fourth secondary PCB winding form a second center-tapped secondary circuit, and the first center-tapped secondary circuit and the second center-tapped secondary circuit are connected in parallel. In some embodiments, the first and second primary PCB windings have 10 turns in total, and each of the first secondary PCB winding, the second secondary PCB winding, the third secondary PCB winding and the fourth secondary PCB winding has 1 turn.

In some embodiments, the first PCB is an 8-layer PCB including a first conductive layer, a second conductive layer, a third conductive layer, a fourth conductive layer, a fifth conductive layer, a sixth conductive layer a seventh conductive layer, and an eighth conductive layer arranged in sequence. The first and second primary PCB windings are formed by the first conductive layer, the second conductive layer, the third conductive layer, the fourth conductive layer and the fifth conductive layer of the first PCB. The single shielding layer is formed by the sixth conductive layer of the first PCB. The first and third secondary PCB windings are formed by the seventh conductive layer of the first PCB. The second and fourth secondary PCB windings are formed by the eighth conductive layer of the first PCB.

In some embodiments, the first PCB is a 6-layer PCB including a first conductive layer, a second conductive layer, a third conductive layer, a fourth conductive layer, a fifth conductive layer, and a sixth conductive layer arranged in sequence. The first and second primary PCB windings are formed by the first conductive layer, the second conductive layer and the third conductive layer of the first PCB. The single shielding layer is formed by the fourth conductive layer of the first PCB. The first and third secondary PCB windings are formed by the fifth conductive layer of the first PCB. The second and fourth secondary PCB windings are formed by the sixth conductive layer of the first PCB.

In some embodiments, the planar transformer assembly further includes a second PCB provided for the first PCB mounted thereon. The second PCB includes a pair of primary MOSFET switches. The first PCB further includes a pair of inductors, a capacitor and at least two pairs of secondary MOSFET switches. The pair of inductors and the capacitor are connected to the pair of primary MOSFET switches to form an LLC structure. The two pairs of secondary MOSFET switches are mounted on a back side of the first PCB board. Some of the secondary MOSFET switches are electrically connected to the first center-tapped secondary circuit and the second center-tapped secondary circuit through vias.

In addition, embodiments provide a power adapter. The power adapter includes a main printed circuit board and an affiliated printed circuit board. The main printed circuit board (PCB) has a pair of primary MOSFET switches and a high potential input port for conducting a modulated high potential current. The affiliated printed circuit board (PCB) is mounted on the main PCB. The affiliated printed circuit board (PCB) includes a primary side circuit and a center-tapped secondary side circuit. The primary side circuit includes primary PCB windings connected in series. The primary side circuit is configured to conduct the modulated high potential current. The center-tapped secondary side circuit includes a top secondary PCB winding circuit and a bottom secondary PCB winding circuit. Both the top secondary PCB winding circuit and the bottom secondary PCB winding circuit are stacked beneath the primary PCB winding circuit.

The power adapter further includes a planar transformer composed of the primary side circuit, the center-tapped secondary side circuit and a single shielding layer. The single shielding layer is sandwiched between the top secondary PCB winding circuit and the primary PCB windings. The shielding layer is connected to a ground terminal for suppressing common mode noise induced on the center-tapped secondary side circuit.

In some embodiments, he affiliated PCB further includes a magnetic core passing through the affiliated PCB. The magnetic core includes a first cover plate, a second cover plate, a side core and a magnetic pillar. The side core affixes the first cover plate and the second cover plate. The magnetic pillar extends from the first cover plate to the second cover plate. The magnetic pillar has a first end and a second end. The first end is connected to the first cover plate. The second end is adjacent to and separated from the second cover plate by an air gap.

In some embodiments, the primary side circuit and the center-tapped secondary side circuit are wrapped around the magnetic pillar. In some embodiments, the primary side circuit is closer to the air gap than the center-tapped secondary side circuit. In some embodiments, the primary side circuit is stacked on the center-tapped secondary side circuit in an extension direction of the magnetic pillar to generate excitation current flowing through the center-tapped secondary side circuit.

In some embodiments, the affiliated PCB further includes a pair of magnetizing inductors, a capacitor, a resonant inductor and at least two pairs of secondary MOSFET switches. The pair of magnetizing inductors, the capacitor and a resonant inductor are connected to the pair of primary MOSFET switches to form an LLC structure. The LLC structure is configured to provide the high potential input ports with the modulated high potential current. The two pairs of secondary MOSFET switches are mounted on a back side of the affiliated PCB. One of the secondary MOSFET switches is electrically connected to the top secondary PCB winding circuit, and without being connected to the bottom secondary PCB winding circuit, through vias.

In some embodiments, the top secondary PCB winding circuit and the bottom secondary PCB winding circuit are connected in parallel. In some embodiments, a first distance between the pair of primary MOSFET switches and the high potential input port is greater than a second distance between the secondary MOSFET switches and the output via. In some embodiments, the turns ratio of primary PCB windings of the primary PCB winding circuit to a secondary PCB winding wound clockwise or anti-clockwise in each of the top secondary PCB winding circuit and the bottom secondary PCB winding circuit is 10:1.

In some embodiments, the affiliated PCB is an 8-layer PCB including a first conductive layer, a second conductive layer, a third conductive layer, a fourth conductive layer, a fifth conductive layer, a sixth conductive layer, a seventh conductive layer, and an eighth conductive layer arranged in sequence. The primary PCB winding circuit is formed by the first conductive layer, the second conductive layer, the third conductive layer, the fourth conductive layer, and the fifth conductive layer of the affiliated PCB. The single shielding layer is formed by the sixth conductive layer of the affiliated PCB. The top secondary PCB winding circuit and the bottom secondary PCB winding circuit are formed by the seventh conductive layer and the eighth conductive layer of the affiliated PCB. Each of the primary PCB windings of the primary PCB winding circuit has a 1-turn conductive trace in each of the first conductive layer, the second conductive layer, the third conductive layer, the fourth conductive layer, and the fifth conductive layer.

In some embodiments, the affiliated PCB is a 6-layer PCB including a first conductive layer, a second conductive layer, a third conductive layer, a fourth conductive layer, a fifth conductive layer, and a sixth conductive layer arranged in sequence. The primary PCB winding circuit is formed on the first conductive layer, the second conductive layer, and the third conductive layer of the affiliated PCB. The single shielding layer is formed on the fourth conductive layer of the affiliated PCB. The top secondary PCB winding circuit and the bottom secondary PCB winding circuit are formed on the fifth conductive layer and the sixth conductive layer of the affiliated PCB. Each of the primary PCB windings of the primary PCB winding circuit has two 2-turn conductive traces in two of the first conductive layer, the second conductive layer, and the third conductive layer.

In some embodiments, the planar transformer assembly (e.g., the power adapter) is composed of multiple PCBs to increase the area for the arrangements of the primary-side signal generating circuit, the planar transformer, and the secondary-side rectifying circuit in the limited product size. In some embodiments, the planar transformer uses a single shielding layer disposed at a single side of the primary side circuit (including the primary PCB windings) to isolate the primary side circuit and the center-tapped secondary side circuit (including the secondary PCB windings of the top secondary PCB winding circuit and the bottom secondary PCB winding circuit). In some embodiments, the turns ratio of the primary PCB windings to the secondary PCB winding wound clockwise or anti-clockwise in each of the top secondary PCB winding circuit and the bottom secondary PCB winding circuit is about 10:1. Compared with the conventional planar transformer which uses two shielding layers to isolate the primary and secondary windings, the planar transformer of the planar transformer assembly may provide at least one additional PCB conductive layer for the primary PCB windings. Therefore, the resistance (e.g., DC resistance, R_{dc}) of the primary windings can be reduced. In addition, the secondary PCB windings are arranged away from the air gaps of the magnetic core. Compared with the conventional planar transformer, the current flow induced in the secondary PCB windings of the planar transformer of the planar transformer assembly is more uniform. Moreover, the planar transformer assembly may use a 6-layer PCB or an 8-layer PCB using double-sided PCB manufacturing process to form the primary and secondary PCB windings of the planar transformer by considering the tradeoff between the impedance, leakage inductance, power loss, and the fabrication costs.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A planar transformer assembly, comprising:
a first printed circuit board (PCB), comprising:
a magnetic core passing through the first PCB, wherein the magnetic core comprises:
a first cover plate;
a second cover plate opposite the first cover plate; and
a first magnetic pillar connected to the first cover plate and extending from the first cover plate to the second cover plate, wherein the first magnetic pillar is separated from the second cover plate by a first air gap,
a first primary PCB winding wrapped around a first portion of the first magnetic pillar; and
a first secondary PCB winding and a second secondary PCB winding wrapped around a second portion of the first magnetic pillar below the first portion of the first magnetic pillar, wherein the second portion is a single portion of the first magnetic pillar.

2. The planar transformer assembly as claimed in claim 1, wherein the first PCB further comprises:
a single shielding layer located below the first primary PCB winding and above the first secondary PCB winding and the second secondary PCB winding, wherein the shielding layer is connected to a ground terminal.

3. The planar transformer assembly as claimed in claim 1, wherein the first portion of the first magnetic pillar is closer to the first air gap than the second portion of the first magnetic pillar.

4. The planar transformer assembly as claimed in claim 2, wherein each of the first secondary PCB winding and the second secondary PCB winding has a first terminal and a second terminal, and the second terminal of the first secondary PCB winding is connected to the first terminal of the second secondary PCB winding.

5. The planar transformer assembly as claimed in claim 3, wherein the magnetic core further comprises:
a second magnetic pillar beside the first magnetic pillar, wherein the second magnetic pillar is connected to the first cover plate and extends from the first cover plate to the second cover plate, and wherein the second magnetic pillar is separated from the second cover plate by a second air gap.

6. The planar transformer assembly as claimed in claim 5, wherein the first PCB further comprises:
a second primary PCB winding wrapped around a third portion of the second magnetic pillar, wherein the first primary PCB winding and the second primary PCB winding are connected in series; and
a third secondary PCB winding and a fourth secondary PCB winding wrapped around a fourth portion of the second magnetic pillar below the third portion of the second magnetic pillar, wherein the fourth portion is a single portion of the second magnetic pillar.

7. The planar transformer assembly as claimed in claim 6, wherein the third portion of the second magnetic pillar is closer to the second air gap than the fourth portion of the second magnetic pillar.

8. The planar transformer assembly as claimed in claim 6, wherein each of the third secondary PCB winding and the fourth secondary PCB winding has a third terminal and a fourth terminal, and the fourth terminal of the third secondary PCB winding is connected to the third terminal of the fourth secondary PCB winding.

9. The planar transformer assembly as claimed in claim 8, wherein the first secondary PCB winding and the second secondary PCB winding form a first center-tapped secondary circuit, the third secondary PCB winding and the fourth secondary PCB winding form a second center-tapped secondary circuit, and the first center-tapped secondary circuit and the second center-tapped secondary circuit are connected in parallel.

10. The planar transformer assembly as claimed in claim 9, wherein the first and second primary PCB windings have 10 turns in total, and each of the first secondary PCB winding, the second secondary PCB winding, the third secondary PCB winding and the fourth secondary PCB winding has 1 turn.

11. The planar transformer assembly as claimed in claim 10, wherein:
the first PCB is an 8-layer PCB comprises a first conductive layer, a second conductive layer, a third conductive layer, a fourth conductive layer, a fifth conductive layer, a sixth conductive layer, a seventh conductive layer, and an eighth conductive layer arranged in sequence,
the first and second primary PCB windings are formed by the first conductive layer, the second conductive layer, the third conductive layer, the fourth conductive layer and the fifth conductive layer of the first PCB,
the single shielding layer is formed by the sixth conductive layer of the first PCB,
the first and third secondary PCB windings are formed by the seventh conductive layer of the first PCB, and
the second and fourth secondary PCB windings are formed by the eighth conductive layer of the first PCB.

12. The planar transformer assembly as claimed in claim 10, wherein:
the first PCB is a 6-layer PCB comprises a first conductive layer, a second conductive layer, a third conductive layer, a fourth conductive layer, a fifth conductive layer, and a sixth conductive layer arranged in sequence,
the first and second primary PCB windings are formed by the first conductive layer, the second conductive layer and the third conductive layer of the first PCB,
the single shielding layer is formed by the fourth conductive layer of the first PCB,
the first and third secondary PCB windings are formed by the fifth conductive layer of the first PCB, and
the second and fourth secondary PCB windings are formed by the sixth conductive layer of the first PCB.

13. The planar transformer assembly as claimed in claim 10, further comprising:
a second PCB provided for the first PCB mounted thereon, wherein the second PCB comprises:
a pair of primary MOSFET switches,
wherein the first PCB further comprises:
a pair of inductors and a capacitor connected to the pair of primary MOSFET switches to form an LLC structure; and
at least two pairs of secondary MOSFET switches mounted on a back side of the first PCB board, and some of the secondary MOSFET switches are electrically connected to the first center-tapped secondary circuit and the second center-tapped secondary circuit through vias.

14. A power adapter, comprising:
a main printed circuit board (PCB) having a pair of primary MOSFET switches and a high potential input port for conducting a modulated high potential current; and
an affiliated printed circuit board (PCB) mounted on the main PCB, wherein the affiliated PCB comprises:
a primary side circuit comprising primary PCB windings connected in series, wherein the primary side circuit is configured to conduct the modulated high potential current; and
a center-tapped secondary side circuit comprising a top secondary PCB winding circuit and a bottom secondary PCB winding circuit, wherein both the top secondary PCB winding circuit and the bottom secondary PCB winding circuit are stacked beneath the primary PCB winding circuit.

15. The power adapter as claimed in claim 14, wherein the affiliated PCB further comprises:
a single shielding layer sandwiched between the top secondary PCB winding circuit and the primary PCB winding circuit, wherein the shielding layer is connected to a ground terminal for suppressing common mode noise induced on the center-tapped secondary side circuit.

16. The power adapter as claimed in claim 14, wherein the affiliated PCB further comprises a magnetic core passing through the affiliated PCB, wherein the magnetic core comprises:
a first cover plate;
a second cover plate;
a side core affixing the first cover plate and the second cover plate; and
a magnetic pillar extending from the first cover plate to the second cover plate, wherein the magnetic pillar has a first end and a second end, the first end is connected to the first cover plate, and the second end is adjacent to and separated from the second cover plate by an air gap.

17. The power adapter as claimed in claim 16, wherein the primary side circuit and the center-tapped secondary side circuit are wrapped around the magnetic pillar.

18. The power adapter as claimed in claim 16, wherein the primary side circuit is closer to the air gap than the center-tapped secondary side circuit.

19. The power adapter assembly as claimed in claim 14, wherein the primary side circuit is stacked on the center-tapped secondary side circuit in an extension direction of the magnetic pillar to generate excitation current flowing through the center-tapped secondary side circuit.

20. The power adapter as claimed in claim 14, wherein the affiliated PCB further comprises:
a pair of magnetizing inductors, a capacitor and a resonant inductor connected to the pair of primary MOSFET switches to form an LLC structure, wherein the LLC structure is configured to provide the high potential input ports with the modulated high potential current;
at least two pairs of secondary MOSFET switches mounted on a back side of the affiliated PCB, wherein one of the secondary MOSFET switches (is electrically connected to the top secondary PCB winding circuit, and without being connected to the bottom secondary PCB winding circuit, through vias.

21. The power adapter as claimed in claim 14, wherein the top secondary PCB winding circuit and the bottom secondary PCB winding circuit are connected in parallel.

22. The power adapter as claimed in claim 14, wherein a first distance between the pair of primary MOSFET switches and the high potential input port is greater than a second distance between the secondary MOSFET switches and the output vias.

23. The power adapter as claimed in claim 14, wherein a turns ratio of primary PCB windings of the primary PCB winding circuit to a secondary PCB winding wound clockwise or anti-clockwise in each of the top secondary PCB winding circuit and the bottom secondary PCB winding circuit is 10:1.

24. The power adapter as claimed in claim 15, wherein:
the affiliated PCB is an 8-layer PCB comprises a first conductive layer, a second conductive layer, a third conductive layer, a fourth conductive layer, a fifth conductive layer, a sixth conductive layer, a seventh conductive layer, and an eighth conductive layer arranged in sequence,
the primary PCB winding circuit is formed by the first conductive layer, the second conductive layer, the third conductive layer, the fourth conductive layer, and the fifth conductive layer of the affiliated PCB,
the single shielding layer is formed by the sixth conductive layer of the affiliated PCB,
the top secondary PCB winding circuit and the bottom secondary PCB winding circuit are formed by the seventh conductive layer and the eighth conductive layer of the affiliated PCB, and
each of the primary PCB windings of the primary PCB winding circuit has a 1-turn conductive trace in each of the first conductive layer, the second conductive layer, the third conductive layer, the fourth conductive layer, and the fifth conductive layer.

25. The power adapter as claimed in claim 15, wherein:
the affiliated PCB is a 6-layer PCB comprises a first conductive layer, a second conductive layer, a third conductive layer, a fourth conductive layer, a fifth conductive layer, and a sixth conductive layer arranged in sequence,
the primary PCB winding circuit is formed on the first conductive layer, the second conductive layer, and the third conductive layer of the affiliated PCB,
the single shielding layer is formed on the fourth conductive layer of the affiliated PCB,
the top secondary PCB winding circuit and the bottom secondary PCB winding circuit are formed on the fifth conductive layer and the sixth conductive layer of the affiliated PCB, and
each of the primary PCB windings of the primary PCB winding circuit has two 2-turn conductive traces in two of the first conductive layer, the second conductive layer, and the third conductive layer.
